(19) United States
(12) Patent Application Publication
(10) Pub. No.: US 2021/0359273 A1
(43) Pub. Date: Nov. 18, 2021

(54) DISPLAY DEVICE WITH FINGERPRINT IDENTIFICATION FUNCTION AND MANUFACTURING METHOD THEREOF

(71) Applicant: WUHAN CHINA STAR OPTOELECTRONICS SEMICONDUCTOR DISPLAY TECHNOLOGY CO., LTD., Wuhan, Hubei (CN)

(72) Inventors: Yalong Ma, Wuhan (CN); Yichao Deng, Wuhan (CN); Qibing Dai, Wuhan (CN)

(21) Appl. No.: 16/488,409

(22) PCT Filed: Apr. 15, 2019
(86) PCT No.: PCT/CN2019/082697

§ 371 Date: Aug. 23, 2019

(30) Foreign Application Priority Data
Jan. 30, 2019 (CN) 201910093564.7

(51) Int. Cl. H01L 51/52; G06K 9/00; H01L 51/56

(52) U.S. Cl. CPC H01L 51/5275; G06K 9/0004; H01L 51/5225; H01L 27/3244; H01L 51/56; H01L 51/5253; H01L 51/5234

(57) ABSTRACT

A display device with a fingerprint identification function includes: a fingerprint identification module configured to sense a fingerprint; a substrate disposed on the fingerprint identification module; a plurality of anodes disposed on the substrate; a plurality of light emitting elements disposed on the anodes; a plurality of cathodes disposed on the light emitting elements, wherein each of the cathodes has a pillar shape; and a protective layer disposed between two adjacent ones of the cathodes, wherein a refractive index of each of the cathodes is smaller than a refractive index of the protective layer. A manufacturing method of a display device with a fingerprint identification function is further provided.

### BACKGROUND

### Field

The present disclosure relates to the technical field of display devices, and more particularly to a display device with a fingerprint identification function and a manufacturing method thereof.

### Background

In the optical technology included in the in-display fingerprint identification technology, an organic light-emitting layer of an active-matrix organic light-emitting diode (AMOLED) display device emits light toward various directions. Refraction and reflection occur when the emitted light reaches a glass/air interface on one surface of a cover glass (CG). Assuming that the refractive index of the air is n1 and the refractive index of the cover glass is n2. When an incident angle θ of the light reaching the cover glass is greater than arcsin(n1/n2) (i.e., a computation of the arcsine of a ratio of n1 to n2), total reflection occurs.

When a fingerprint presses the surface of the cover glass, the surface of the cover glass is still the glass/air interface due to valley portions of the fingerprint (i.e., portions of the fingerprint not touching the cover glass). Accordingly, the total reflection occurs (the refractive index of the glass is greater than the refractive index of the air).

The surface of the cover glass is a glass/sweat interface due to ridge portions of the fingerprint (i.e., portions of the fingerprint touching the cover glass). Since a refractive index of the sweat is approximately equal to the refractive index of the glass, a total reflection angle is approximately equal to 90 degrees. That is, the total reflection does not occur.

In summary, light reflected in areas of the active-matrix organic light-emitting diode display device corresponding to the valley portions of the fingerprint (i.e., portions of the fingerprint not touching the cover glass) is more than light reflected in areas of the active-matrix organic light-emitting diode display device corresponding to the ridge portions of the fingerprint (i.e., portions of the fingerprint touching the cover glass). Accordingly, a fingerprint image can be formed by bright and dark differences, thereby achieving the fingerprint identification.

However, in the conventional active-matrix organic light-emitting diode display device, the bright and dark differences between the areas of the active-matrix organic light-emitting diode display device corresponding to the valley portions of the fingerprint and the areas of the active-matrix organic light-emitting diode display device corresponding to the ridge portions of the fingerprint are not apparent. This leads to the problem that the fingerprint identification is not sensitive. In detail, total reflection light in the areas corresponding to the valley portions of the fingerprint is not enough.

Consequently, there is a need to solve the above-mentioned problem in the prior art.

### SUMMARY OF THE DISCLOSURE

An objective of the present disclosure is to provide a display device with a fingerprint identification function and a manufacturing method thereof capable of solving the problem that the total reflection light in the areas corresponding to the valley portions of the fingerprint is not enough in the prior art.

To solve the above problem, a display device with a fingerprint identification function provided by the present disclosure includes: a fingerprint identification module configured to sense a fingerprint; a substrate disposed on the fingerprint identification module; a plurality of anodes disposed on the substrate; a plurality of light emitting elements disposed on the anodes; a plurality of cathodes disposed on the light emitting elements, wherein each of the cathodes has a cylinder shape; and a protective layer disposed between two adjacent ones of the cathodes and covering the cathodes, wherein a refractive index of each of the cathodes is smaller than a refractive index of the protective layer, and an axis of each of the cathodes coincides with an axis of a corresponding one of the light emitting elements.

In one embodiment, a diameter of each of the cathodes is greater than a diameter of a corresponding one of the light emitting elements.

In one embodiment, the display device with the fingerprint identification function further includes an encapsulation layer disposed on the protective layer.

In one embodiment, the display device with the fingerprint identification function further includes a cover glass disposed on the encapsulation layer.

To solve the above problem, a display device with a fingerprint identification function provided by the present disclosure includes: a fingerprint identification module configured to sense a fingerprint; a substrate disposed on the fingerprint identification module; a plurality of anodes disposed on the substrate; a plurality of light emitting elements disposed on the anodes; a plurality of cathodes disposed on the light emitting elements, wherein each of the cathodes has a pillar shape; and a protective layer disposed between two adjacent ones of the cathodes, wherein a refractive index of each of the cathodes is smaller than a refractive index of the protective layer.

In one embodiment, the pillar shape is a cylinder shape.

In one embodiment, an axis of each of the cathodes coincides with an axis of a corresponding one of the light emitting elements.

In one embodiment, a diameter of each of the cathodes is greater than a diameter of a corresponding one of the light emitting elements.

In one embodiment, the display device with the fingerprint identification function further includes an encapsulation layer disposed on the protective layer.

In one embodiment, the display device with the fingerprint identification function further includes a cover glass disposed on the encapsulation layer.

To solve the above problem, a manufacturing method of a display device with a fingerprint identification function provided by the present disclosure includes: disposing a substrate on a fingerprint identification module; disposing a plurality of anodes on the substrate; disposing a plurality of light emitting elements on the anodes; disposing a plurality of cathodes on the light emitting elements, wherein each of the cathodes has a pillar shape; and disposing a protective layer between two adjacent ones of the cathodes, wherein a refractive index of each of the cathodes is smaller than a refractive index of the protective layer.

In one embodiment, the pillar shape is a cylinder shape.

In one embodiment, an axis of each of the cathodes coincides with an axis of a corresponding one of the light emitting elements.

In one embodiment, a diameter of each of the cathodes is greater than a diameter of a corresponding one of the light emitting elements.

Compared to the prior art, in the display device with the fingerprint identification function and the manufacturing method thereof according to the present disclosure, the light emitting elements and the protective layer can increase the amount of the total reflection light in the areas corresponding to the valley portions of the fingerprint. Accordingly, the bright and dark differences between the areas corresponding to the valley portions of the fingerprint and the areas corresponding to the ridge portions of the fingerprint can be more apparent, thereby improving the sensitivity of the fingerprint identification.

### BRIEF DESCRIPTION OF THE DRAWINGS

FIG. 1 illustrates a display device with a fingerprint identification function in accordance with an embodiment of the present disclosure.

FIG. 2 illustrates an enlarged view of an area A in FIG. 1.

FIG. 3 illustrates a manufacturing method of a display device with a fingerprint identification function in accordance with an embodiment of the present disclosure.

### DETAILED DESCRIPTION OF THE PREFERRED EMBODIMENTS

Hereinafter, exemplary embodiments of the present disclosure will be described with reference to the accompanying drawings for illustrating specific embodiments which can be carried out by the present disclosure.

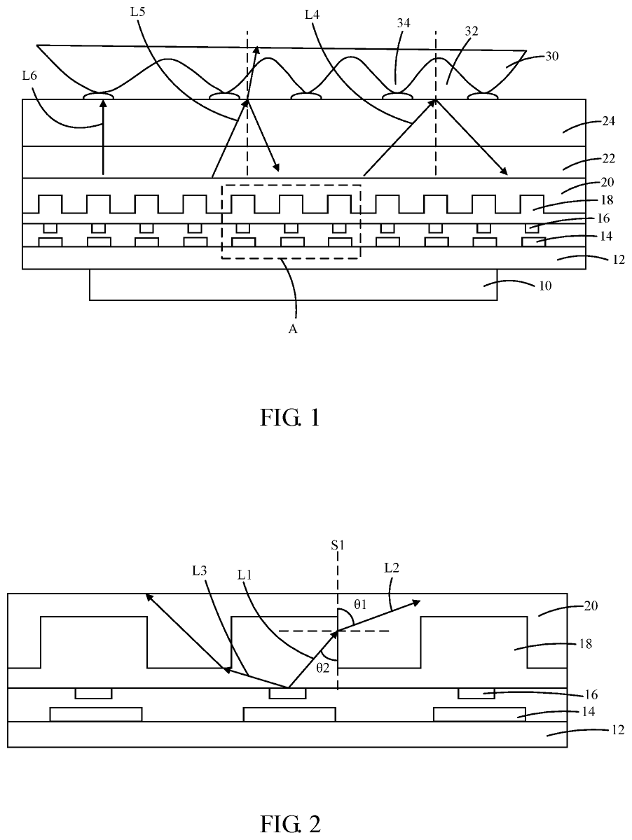

Please refer to FIG. 1 and FIG. 2. FIG. 1 illustrates a display device with a fingerprint identification function in accordance with an embodiment of the present disclosure. FIG. 2 illustrates an enlarged view of an area A in FIG. 1.

The display device may be an active-matrix organic light-emitting diode (AMOLED) display device. The display device includes a fingerprint identification module 10, a substrate 12, a plurality of anodes 14, a plurality of light emitting elements 16, a plurality of cathodes 18, a protective layer 20, an encapsulation layer 22, and a cover glass (CG) 24.

The fingerprint identification module 10 is configured to sense a fingerprint.

The substrate 12 is disposed on the fingerprint identification module 10. The substrate 12 may be a flexible substrate. The substrate 12 includes a thin film transistor layer and corresponding wirings. Detailed structures of the thin film transistor layer and the corresponding wirings are known by those skilled in the art and not repeated herein.

The anodes 14 are disposed on the substrate 12. The anodes 14 are arranged in a matrix.

The light emitting elements 16 are disposed on the anodes 14. Each of the light emitting elements 16 corresponds to one of the anodes 14. In detail, each of the light emitting elements 16 is disposed on one of the anodes 14. The light emitting elements 16 are arranged in a matrix. Each of the light emitting elements 16 can emit a color light, for example but not limited to a red light, a green light, or a blue light. Each of the light emitting elements 16 may correspond to a sub-pixel.

It is noted that a hole injection layer (not shown) and a hole transport layer (not shown) are disposed between the anodes 18 and the light emitting elements 16. The hole injection layer and the hole transport layer are known by those skilled in the art, not the main focus of the present disclosure, and not repeated herein.

The cathodes 18 are disposed on the light emitting elements 16. Each of the cathodes 18 corresponds to one of the light emitting elements 16. In detail, each of the cathodes 18 is disposed on one of the light emitting elements 16. The cathodes 18 are arranged in a matrix.

Each of the cathodes 18 has a pillar shape. In one embodiment, the pillar shape may be but is not limited to a cylinder shape. When each of the cathodes 18 has a cylinder shape, an axis of each of the cathodes 18 coincides with an axis of a corresponding one of the light emitting elements 16 and a diameter of each of the cathodes 18 is greater than a diameter of a corresponding one of the light emitting elements 16.

Furthermore, sizes of the cathodes 18 are the same, and sizes of the light emitting elements 16 are the same. In other words, differences of the cathodes 18 and the corresponding light emitting elements 16 are the same.

It is noted that an electron transport layer (not shown) and an electron injection layer (not shown) are disposed between the light emitting elements 16 and the anodes 18. The electron transport layer and the electron injection layer are known by those skilled in the art, not the main focus of the present disclosure, and not repeated herein.

The protective layer 20 is disposed between two adjacent ones of the cathodes 18 and covers the cathodes 18. In detail, spaces between two adjacent ones of the cathodes 18 are filled with the protective layer 20, and the cathodes 18 are covered by the protective layer 20. A refractive index of each of the cathodes 18 is smaller than a refractive index of the protective layer 20. The protective layer 20 is configured to protect the cathodes 18.

The encapsulation layer 22 is disposed on the protective layer 20. The encapsulation layer 22 is configured to encapsulate the substrate 12, the anodes 14, the light emitting elements 16, the cathodes 18, and the protective layer 20.

The cover glass 24 is disposed on the encapsulation layer 22 and configured to protect the elements inside the display device.

To solve the problem that total reflection light is not enough in the prior art, each of the cathodes 18 has a cylinder shape, and the refractive index of each of the cathodes 18 is smaller than the refractive index of the protective layer 20. Accordingly, as shown in FIG. 2, a light emitting path is changed after light L1 emitted by the light emitting element 16 reaches a side wall of the cathode 18. That is, an angle θ1 between refracted light L2 and an interface S1 (between the cathode 18 and the protective layer 20) is increased. That is, the angle θ1 between the refracted light L2 and the interface S1 is greater than an angle θ2 between emitted light L1 and the interface S1. Since the angle θ1 between refracted light L2 and the interface S1 is increased, light which is not totally reflected in the prior art can be totally reflected. The light which is totally reflected in the prior art (e.g., L3) still can be totally reflected. In summary, the light emitting elements 16 and the protective layer 20 of the present disclosure can increase the amount of the total reflection light.

As shown in FIG. 1, light L4 having a large angle can be totally reflected at an interface between the cover glass 24 and the air. Some of light L5 having a small angle is reflected at the interface between the cover glass 24 and the air, and some of the light L5 is refracted. Vertical light L6 is not reflected.

When a fingerprint 30 presses one surface of the cover glass 24, the surface of the cover glass 24 is still the glass/air interface due to valley portions 32 of the fingerprint 30 (i.e., portions of the fingerprint 30 not touching the cover glass 24). Accordingly, the total reflection occurs (the refractive index of the glass is greater than the refractive index of the air).

The surface of the cover glass 24 is a glass/sweat interface due to ridge portions 34 of the fingerprint 30 (i.e., portions of the fingerprint 30 touching the cover glass 24). Since a refractive index of the sweat is approximately equal to the refractive index of the glass, a total reflection angle is approximately equal to 90 degrees. That is, the total reflection does not occur.

In summary, light reflected in areas of the display device corresponding to the valley portions 32 of the fingerprint 30 is more than light reflected in areas of the display device corresponding to the ridge portions 34 of the fingerprint 30. Accordingly, a fingerprint image can be formed by bright and dark differences, thereby achieving the fingerprint identification.

As mentioned above, the light emitting elements 16 and the protective layer 20 of the present disclosure can increase the amount of the total reflection light in the areas of the display device corresponding to the valley portions 32 of the fingerprint 30. Accordingly, the bright and dark differences between the areas of the display device corresponding to the valley portions 32 of the fingerprint 30 and the areas of the display device corresponding to the ridge portions 34 of the fingerprint 30 can be more apparent, thereby improving the sensitivity of the fingerprint identification.

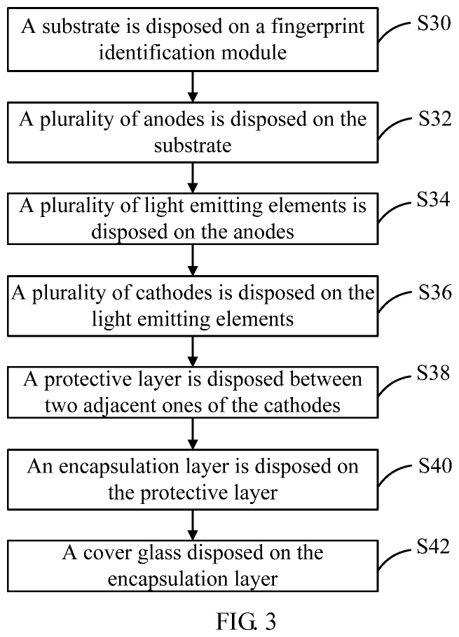

Please refer to FIG. 3. FIG. 3 illustrates a manufacturing method of a display device with a fingerprint identification function in accordance with an embodiment of the present disclosure.

In operation S30, a substrate is disposed on a fingerprint identification module.

The fingerprint identification module is configured to sense a fingerprint.

In operation S32, a plurality of anodes is disposed on the substrate.

In operation S34, a plurality of light emitting elements is disposed on the anodes.

In operation S36, a plurality of cathodes is disposed on the light emitting elements. Each of the cathodes has a pillar shape.

In one embodiment, the pillar shape may be but is not limited to a cylinder shape. When each of the cathodes has a cylinder shape, an axis of each of the cathodes coincides with an axis of a corresponding one of the light emitting elements and a diameter of each of the cathodes is greater than a diameter of a corresponding one of the light emitting elements.

Furthermore, sizes of the cathodes are the same, and sizes of the light emitting elements are the same. In other words, differences of the cathodes and the corresponding light emitting elements are the same.

In operation S38, a protective layer is disposed between two adjacent ones of the cathodes. A refractive index of each of the cathodes is smaller than a refractive index of the protective layer.

In detail, spaces between two adjacent ones of the cathodes are filled with the protective layer, and the cathodes are covered by the protective layer.

In operation S40, an encapsulation layer is disposed on the protective layer.

The encapsulation layer is configured to encapsulate the substrate, the anodes, the light emitting elements, the cathodes, and the protective layer.

In operation S42, a cover glass disposed on the encapsulation layer.

The cover glass is configured to protect the elements inside the display device.

In the display device with the fingerprint identification function and the manufacturing method thereof according to the present disclosure, the light emitting elements and the protective layer can increase the amount of the total reflection light in the areas corresponding to the valley portions of the fingerprint. Accordingly, the bright and dark differences between the areas corresponding to the valley portions of the fingerprint and the areas corresponding to the ridge portions of the fingerprint can be more apparent, thereby improving the sensitivity of the fingerprint identification.

In summary, although the present disclosure has been provided in the preferred embodiments described above, the foregoing preferred embodiments are not intended to limit the present disclosure. Those skilled in the art, without departing from the spirit and scope of the present disclosure, may make modifications and variations, so the scope of the protection of the present disclosure is defined by the claims.

What is claimed is:

1. A display device with a fingerprint identification function, comprising:
a fingerprint identification module configured to sense a fingerprint;
a substrate disposed on the fingerprint identification module;
a plurality of anodes disposed on the substrate;
a plurality of light emitting elements disposed on the anodes;
a plurality of cathodes disposed on the light emitting elements, wherein each of the cathodes has a cylinder shape; and
a protective layer disposed between two adjacent ones of the cathodes and covering the cathodes, wherein a refractive index of each of the cathodes is smaller than a refractive index of the protective layer, and an axis of each of the cathodes coincides with an axis of a corresponding one of the light emitting elements.

2. The display device with the fingerprint identification function of claim 1, wherein a diameter of each of the cathodes is greater than a diameter of a corresponding one of the light emitting elements.

3. The display device with the fingerprint identification function of claim 1, further comprising:
an encapsulation layer disposed on the protective layer.

4. The display device with the fingerprint identification function of claim 3, further comprising:
a cover glass disposed on the encapsulation layer.

5. A display device with a fingerprint identification function, comprising:
a fingerprint identification module configured to sense a fingerprint;
a substrate disposed on the fingerprint identification module;
a plurality of anodes disposed on the substrate;
a plurality of light emitting elements disposed on the anodes;
a plurality of cathodes disposed on the light emitting elements, wherein each of the cathodes has a pillar shape; and
a protective layer disposed between two adjacent ones of the cathodes, wherein a refractive index of each of the cathodes is smaller than a refractive index of the protective layer.

6. The display device with the fingerprint identification function of claim 5, wherein the pillar shape is a cylinder shape.

7. The display device with the fingerprint identification function of claim 6, wherein an axis of each of the cathodes coincides with an axis of a corresponding one of the light emitting elements.

8. The display device with the fingerprint identification function of claim 7, wherein a diameter of each of the cathodes is greater than a diameter of a corresponding one of the light emitting elements.

9. The display device with the fingerprint identification function of claim 5, further comprising:
an encapsulation layer disposed on the protective layer.

10. The display device with the fingerprint identification function of claim 9, further comprising:
a cover glass disposed on the encapsulation layer.

11. A manufacturing method of a display device with a fingerprint identification function, comprising:
disposing a substrate on a fingerprint identification module;
disposing a plurality of anodes on the substrate;
disposing a plurality of light emitting elements on the anodes;
disposing a plurality of cathodes on the light emitting elements, wherein each of the cathodes has a pillar shape; and
disposing a protective layer between two adjacent ones of the cathodes, wherein a refractive index of each of the cathodes is smaller than a refractive index of the protective layer.

12. The manufacturing method of the display device with the fingerprint identification function of claim 11, wherein the pillar shape is a cylinder shape.

13. The manufacturing method of the display device with the fingerprint identification function of claim 12, wherein an axis of each of the cathodes coincides with an axis of a corresponding one of the light emitting elements.

14. The manufacturing method of the display device with the fingerprint identification function of claim 13, wherein a diameter of each of the cathodes is greater than a diameter of a corresponding one of the light emitting elements.
